(19) United States
(12) Patent Application Publication
(10) Pub. No.: US 2026/0123352 A1
(43) Pub. Date: Apr. 30, 2026

(54) SUBSTRATE SUPPORT APPARATUS AND METHOD OF MANUFACTURING SEMICONDUCTOR DEVICE

(71) Applicant: Samsung Electronics Co., Ltd., Suwon-si (KR)

(72) Inventors: HOSEOK JEONG, Suwon-si (KR); JUNGSU KIM, Suwon-si (KR); HYUNGJOO AN, Suwon-si (KR); SUNGMAN LEE, Suwon-si (KR); JAEHYUNG LEE, Suwon-si (KR); JAE-HEUNG LEE, Suwon-si (KR); HYUNGJUN HAM, Suwon-si (KR)

(21) Appl. No.: 19/005,349

(22) Filed: Dec. 30, 2024

(30) Foreign Application Priority Data
Mar. 13, 2024 (KR) 10-2024-0035116

(51) Int. Cl. H01L 21/687; H01L 21/673

(52) U.S. Cl. CPC H10P 72/7624; H10P 72/145; H10P 72/18; H10P 72/7614

(57) ABSTRACT

A substrate support apparatus includes a lower support having a plate shape and having a first axis as a central axis extending in a vertical direction, an upper support on the lower support, and a connector connecting the lower support and the upper support, wherein the connector includes a connection pillar extending parallel to the first axis and at least one substrate support connected to the connection pillar and extending from the connection pillar toward the first axis, an upper surface of the at least one substrate support includes a first upper surface connected to the connection pillar and a second upper surface positioned at a vertical level lower than a vertical level of the first upper surface, and a first distance between the first upper surface and the first axis is larger than a second distance between the second upper surface and the first axis.

### CROSS-REFERENCE TO RELATED APPLICATIONS

This U.S. non-provisional patent application claims priority under 35 U.S.C. § 119 to Korean Patent Application No. 10-2024-0035116, filed on Mar. 13, 2024, in the Korean Intellectual Property Office, the entire contents of which are hereby incorporated by reference.

### BACKGROUND OF THE INVENTION

Aspects of the inventive concept relate to a substrate support apparatus, and more particularly, relate to a substrate support apparatus including a connector that provides a plurality of grooves or includes a stepped surface.

Semiconductor devices may be manufactured through several processes. When processes such as deposition and etching are performed, multiple semiconductor substrates may be input into a process chamber at once. In this case, a substrate support apparatus such as a semiconductor wafer boat may be used to transport, accommodate, and support a plurality of semiconductor substrates. A substrate support apparatus may hold multiple wafers and may load and unload the wafers into a process chamber. The substrate support apparatus may be designed and manufactured so as not to lose durability even under harsh processing conditions such as high temperature environments.

### SUMMARY

An object of the inventive concept is to provide a substrate support apparatus capable of expanding the surface area of a connector.

An object of the inventive concept is to provide a substrate support apparatus capable of expanding the contact area between a substrate support and a substrate by processing an upper surface of the substrate support.

An object of the inventive concept is to provide a substrate support apparatus capable of expanding the surface area of a substrate support by processing a lower surface of the substrate support to provide a groove.

An object of the inventive concept is to provide a substrate support apparatus capable of expanding the surface area of a connection pillar by processing the connection pillar and providing a groove.

The problem to be solved by the inventive concept is not limited to the problems mentioned above, and other problems not mentioned will be clearly understood by those skilled in the art from the description below.

A substrate support apparatus according to some embodiments of the inventive concept may include a lower support having a plate shape and having a first axis as a central axis extending in a vertical direction perpendicular to a horizontal plane of the lower support; an upper support on the lower support; and a connector connecting the lower support to the upper support, wherein the connector includes: a connection pillar extending parallel to the first axis; and at least one substrate support connected to the connection pillar and extending from the connection pillar toward the first axis, wherein an upper surface of the at least one substrate support includes: a first upper surface connected to the connection pillar; and a second upper surface positioned at a vertical level lower than a vertical level of the first upper surface, and wherein a first distance between the first upper surface and the first axis is larger than a second distance between the second upper surface and the first axis.

A substrate support apparatus according to some embodiments of the inventive concept may include a lower support having a plate shape and having a first axis as a central axis extending in a vertical direction perpendicular to a horizontal plane of the lower support; an upper support on the lower support; and a connector connecting the lower support to the upper support, wherein the connector includes: a connection pillar extending parallel to the first axis; and at least one substrate support extending from the connection pillar toward the first axis, and wherein each of the at least one substrate support includes at least one first groove recessed from a lower surface of the at least one substrate support toward an upper surface of the at least one substrate support.

A substrate support apparatus according to some embodiments of the inventive concept may include a lower support having a plate shape and having a first axis as a central axis extending in a vertical direction perpendicular to a horizontal plane of the lower support; an upper support on the lower support; and a connector connecting the lower support to the upper support, wherein the connector includes: a connection pillar extending parallel to the first axis; and at least one substrate support extending from the connection pillar toward the first axis, and wherein the connection pillar includes a groove recessed from an inner surface of the connection pillar toward an outer surface of the connection pillar.

A method of manufacturing a semiconductor device according to some embodiments of the inventive concept may include loading a substrate onto a substrate support included in a substrate support device while the substrate support device is in a lower chamber of a substrate processing apparatus; moving the substrate support device from the lower chamber of the substrate processing apparatus to an upper chamber of the substrate processing apparatus; supplying a process gas to an inner tube of the substrate processing apparatus and performing a deposition process on the substrate using the supplied process gas; moving the substrate support device from the upper chamber of the substrate processing apparatus to the lower chamber of the substrate processing apparatus; cutting the substrate upon which the deposition process has been performed to form at least one semiconductor device, wherein an upper surface of the at least one substrate support includes: a first upper surface connected to a connection pillar of the substrate support device; and a second upper surface positioned at a vertical level lower than a vertical level of the first upper surface, and wherein a first distance between the first upper surface and a central axis of the substrate support device is larger than a second distance between the second upper surface and the central axis.

The substrate support may include at least one first groove recessed from a lower surface of the substrate support toward the upper surface of the substrate support.

The at least one first groove may have one of a straight shape, a wavy shape, and an arc shape when viewed from a bottom view.

The substrate support may include a protrusion extending from the second upper surface in a vertical direction. The second upper surface may surround a portion of the protrusion when viewed in plan view. A vertical level of an upper surface of the protrusion may be higher than the vertical level of the first upper surface.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view showing a substrate processing apparatus according to embodiments of the inventive concept.

FIG. 2 is a cross-sectional view showing a portion of a substrate processing apparatus according to embodiments of the inventive concept.

FIG. 3 is an enlarged cross-sectional view of region ‘X’ in FIG. 2.

FIG. 4 is a perspective view showing a substrate support apparatus according to embodiments of the inventive concept.

FIG. 5 is an enlarged perspective view of a portion of a substrate support apparatus according to embodiments of the inventive concept.

FIG. 6 is a front view showing a portion of a substrate support apparatus according to embodiments of the inventive concept.

FIG. 7 is an enlarged perspective view of a portion of a substrate support apparatus according to embodiments of the inventive concept.

FIG. 8 is a perspective view showing a substrate support apparatus according to embodiments of the inventive concept.

FIG. 9 is a bottom view showing a substrate support according to embodiments of the inventive concept.

FIG. 10 is a bottom view showing a substrate support according to embodiments of the inventive concept.

FIG. 11 is a bottom view showing a substrate support according to embodiments of the inventive concept.

FIG. 12 is a bottom view showing a substrate support according to embodiments of the inventive concept.

FIG. 13 is an enlarged perspective view of a portion of a substrate support apparatus according to embodiments of the inventive concept.

FIG. 14 is an enlarged perspective view of a portion of a substrate support apparatus according to embodiments of the inventive concept.

FIG. 15 is an enlarged perspective view of a portion of a substrate support apparatus according to embodiments of the inventive concept.

FIG. 16 is an enlarged perspective view of a portion of a substrate support apparatus according to embodiments of the inventive concept.

FIG. 17 shows a method of manufacturing a semiconductor device according to embodiments of the inventive concept.

### DETAILED DESCRIPTION

Hereinafter, embodiments of the inventive concept will be described with reference to the attached drawings. The same reference numerals may refer to the same elements throughout the specification.

Hereinafter, D1 may be referred to as a first direction, D2 crossing the first direction D1 may be referred to as a second direction, and D3 crossing each of the first direction D1 and the second direction D2 may be referred to as a third direction.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

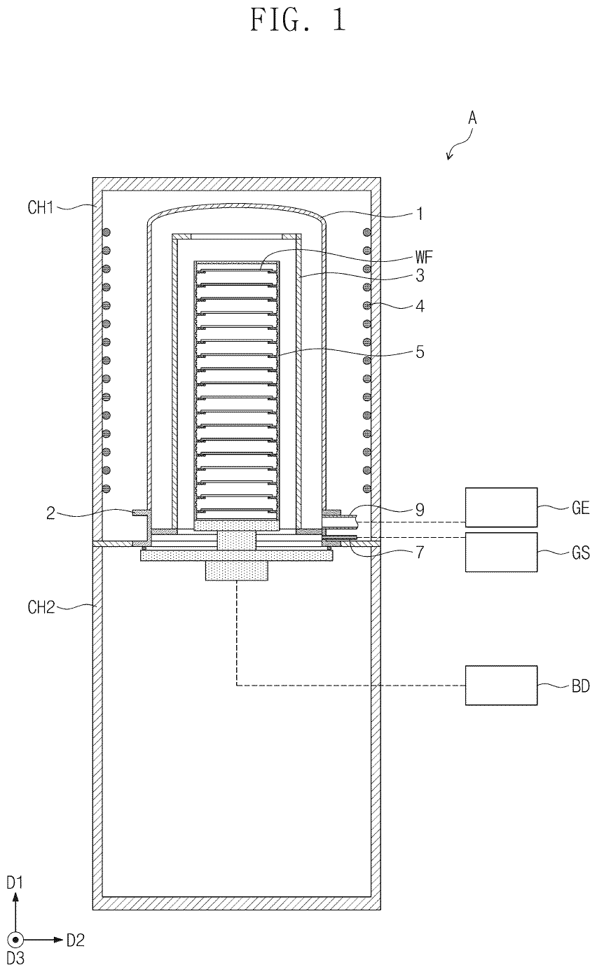

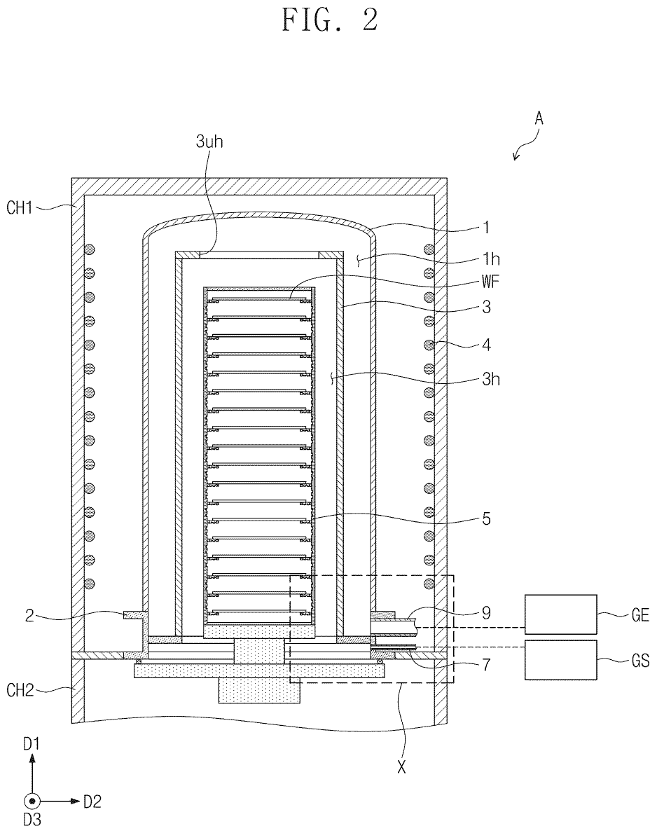

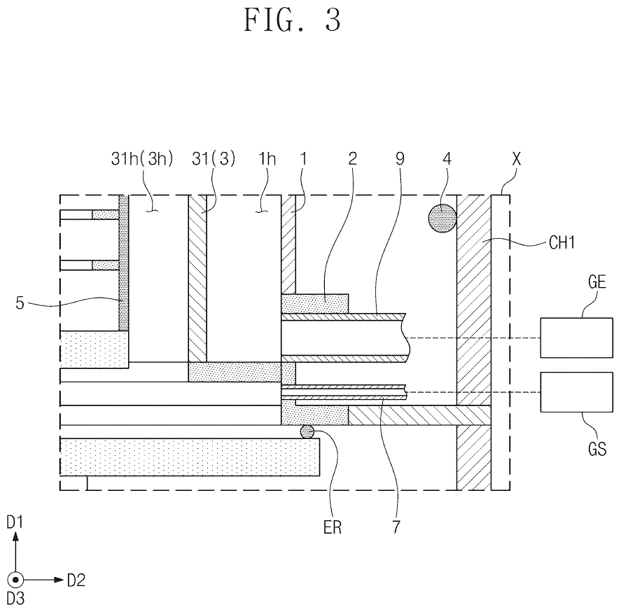

FIG. 1 is a cross-sectional view showing a substrate processing apparatus A according to embodiments of the inventive concept, FIG. 2 is a cross-sectional view showing a portion of a substrate processing apparatus A according to embodiments of the inventive concept, and FIG. 3 is an enlarged cross-sectional view of region ‘X’ in FIG. 2.

Referring to FIG. 1, a substrate processing apparatus A may be provided. The substrate processing apparatus A may be an apparatus that performs a process on a semiconductor substrate WF. The substrate WF used in this specification may mean a silicon (Si) wafer or the like, but is not limited thereto. For example, the substrate processing apparatus A may perform a deposition process on the substrate WF. In detail, the substrate processing apparatus A may perform a low pressure chemical vapor deposition (LPCVD) process on the substrate WF. However, the inventive concept is not limited thereto, and the substrate processing apparatus A may perform other deposition processes such as an atomic layer deposition (ALD) process. The process may proceed with a plurality of substrates WF stacked in the substrate processing apparatus A. To this end, the substrate processing apparatus A may include an upper chamber CH1, a lower chamber CH2, an outer tube 1, an inner tube 3, a substrate support device 5, a gas supply pipe 7, and a gas exhaust pipe 9, a flange 2, and a heater 4. In embodiments, the substrate processing apparatus A may further include a gas supplier GS, a gas exhaust GE, and a substrate support device driver BD.

The upper chamber CH1 may surround the outer tube 1 and the inner tube 3. That is, the outer tube 1, the inner tube 3, and the heater 4 may be disposed in the upper chamber CH1. The upper chamber CH1 may support the heater 4. For example, the heater 4 may be coupled to an inner wall of the upper chamber CH1. However, the inventive concept is not limited thereto, and the heater 4 may be disposed at a position spaced apart from the inner wall of the upper chamber CH1.

The lower chamber CH2 may be disposed below the upper chamber CH1. The substrate support device 5 may move up and down between the lower chamber CH2 and the upper chamber CH1. With the substrate support device 5 disposed in the lower chamber CH2, the substrate WF may be loaded on (or unloaded from) the substrate support device 5. With the substrate support device 5 disposed in the upper chamber CH1, a process on the substrate may proceed.

The outer tube 1 may surround the inner tube 3. A space may be provided between the outer tube 1 and the inner tube 3. That is, an inner surface of the outer tube 1 may be spaced apart from an outer surface of the inner tube 3. The outer tube 1 may be located in the upper chamber CH1. The outer tube 1 may extend in the first direction D1. The outer tube 1 may include, but is not limited to, quartz. The outer tube 1 may surround the inner tube 3. An upper end of the outer tube 1 may be blocked.

As used herein, an item, layer, or portion of an item or layer described as “extending” or as extending “lengthwise” in a particular direction has a length in the particular direction and a width perpendicular to that direction, where the length is greater than the width.

The inner tube 3 may be located in the outer tube 1. The inner tube 3 may extend in the first direction D1. The substrate support device 5 may be arranged in the inner tube 3. In detail, when the substrate support device 5 is lifted and inserted into the upper chamber CH1, the substrate support device 5 may be positioned in the inner tube 3. The inner tube 3 may include, but is not limited to, quartz.

The substrate support device 5 may support the substrate WF. That is, the substrate WF may be placed on the substrate support device 5. A plurality of substrates WF may be loaded on one substrate support device 5 at the same time. The plurality of substrates WF may be arranged in the first direction D1 on the substrate support device 5. However, hereinafter, for convenience, the substrate WF will be described in the singular. The substrate support device 5 may move up and down. For example, the substrate support device 5 may move upward or downward by way of the substrate support device driver BD. A detailed description of the substrate support device 5 will be provided later.

The gas supply pipe 7 may be connected to a space in the inner tube 3. That is, the gas supply pipe 7 may be connected to a process space 3h (refer to FIG. 2). The gas supply pipe 7 may supply process gas into the inner tube 3. The deposition process on the substrate WF on the substrate support device 5 may be performed by the process gas supplied by the gas supply pipe 7.

The gas exhaust pipe 9 may be connected to a space in the outer tube 1. That is, the gas exhaust pipe 9 may be connected to a space between the inner tube 3 and the outer tube 1. The gas exhaust pipe 9 may discharge the process gas supplied by the gas supply pipe 7.

The flange 2 may be located below the outer tube 1. The flange 2 may support the outer tube 1 and/or the inner tube 3. Alternatively, the flange 2 may surround the inner tube 3. The gas supply pipe 7 and/or the gas exhaust pipe 9 may be coupled to the flange 2.

The heater 4 may be located in the upper chamber CH1. For example, the heater 4 may be coupled to the inner wall of the upper chamber CH1. The heater 4 may heat the outer tube 1 and/or the inner tube 3. To this end, the heater 4 may include a heating wire. A plurality of heating wires may be provided. A plurality of heating wires may be arranged in the first direction D1. The plurality of heating wires may be individually controlled. That is, a temperature of each of the plurality of heating wires may be set differently.

The gas supplier GS may supply process gas into the inner tube 3. The gas supplier GS may be connected to the gas supply pipe 7. The gas supplier GS may supply process gas into the inner tube 3 through the gas supply pipe 7. To this end, the gas supplier GS may include a gas tank and/or a compressor.

The gas exhaust GE may exhaust the process gas in the outer tube 1. The gas exhaust GE may be connected to the gas exhaust pipe 9. The gas exhaust GE may exhaust the process gas in the outer tube 1 through the gas exhaust pipe 9. To this end, the gas exhaust GE may include a vacuum pump, etc.

The substrate support device driver BD may move the substrate support device 5. In detail, the substrate support device driver BD may move the substrate support device 5 up and down. To this end, the substrate support device driver BD may include an actuator such as a motor.

Referring to FIG. 2, the inner tube 3 may provide a process space 3h. The process space 3h may extend in the first direction D1. The outer tube 1 may provide an outer space 1h. The outer space 1h may refer to a space between an inner surface of the outer tube 1 and an outer surface of the inner tube 3.

An upper end of the inner tube 3 may be open. For example, the inner tube 3 may provide an outlet 3uh at the upper end thereof. Accordingly, the process space 3h may be connected to the outer space 1h through the outlet 3uh.

FIG. 2 shows that the upper end of the inner tube 3 is open and the process space 3h is connected to the outer space 1h, but the inventive concept is not limited thereto. That is, the upper end of the inner tube 3 may be closed.

Referring to FIG. 3, the gas supply pipe 7 may be coupled to the flange 2. In detail, the gas supply pipe 7 may pass through the flange 2 in a horizontal direction. Additionally, the gas supply pipe 7 may be connected to the process space 3h. The process gas supplied from the gas supplier GS may flow into the process space 3h through the gas supply pipe 7. The process gas flowing into the process space 3h may move upward along the inner surface of the inner tube 3.

The gas exhaust pipe 9 may be coupled to the flange 2. In detail, the gas exhaust pipe 9 may pass through the flange 2 in the horizontal direction. The gas exhaust pipe 9 may be connected to the outer space 1h. The process gas in the outer space 1h may be exhausted to the gas exhaust GE through the gas exhaust pipe 9.

A sealing member ER may be provided below the flange 2. The sealing member ER may prevent the process gas in the process space 3h and/or the outer space 1h from leaking downward, between a support member (not shown) supporting the substate support device and the flange 2.

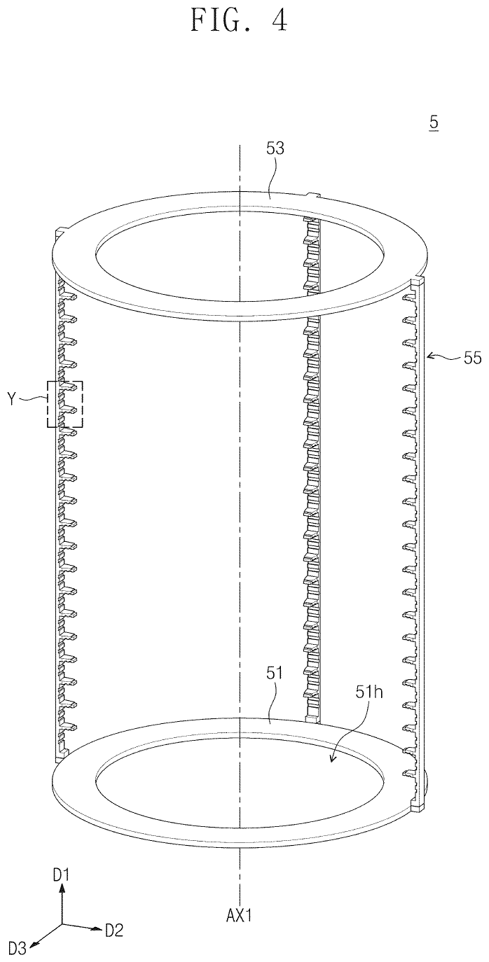

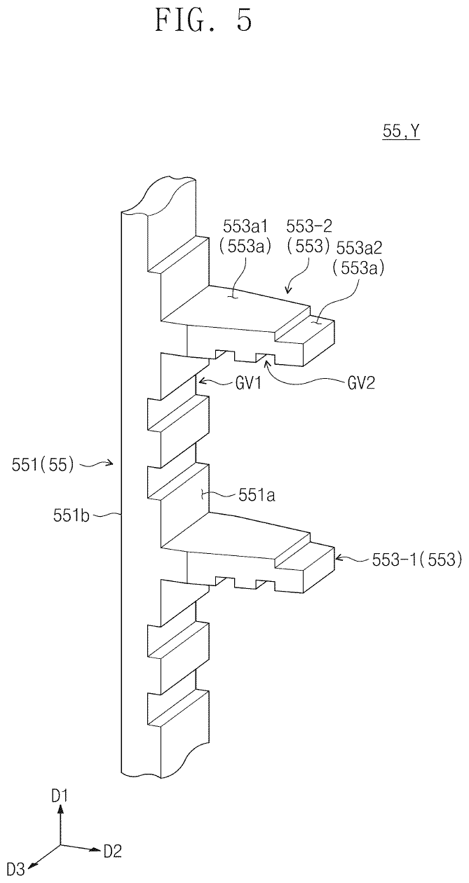

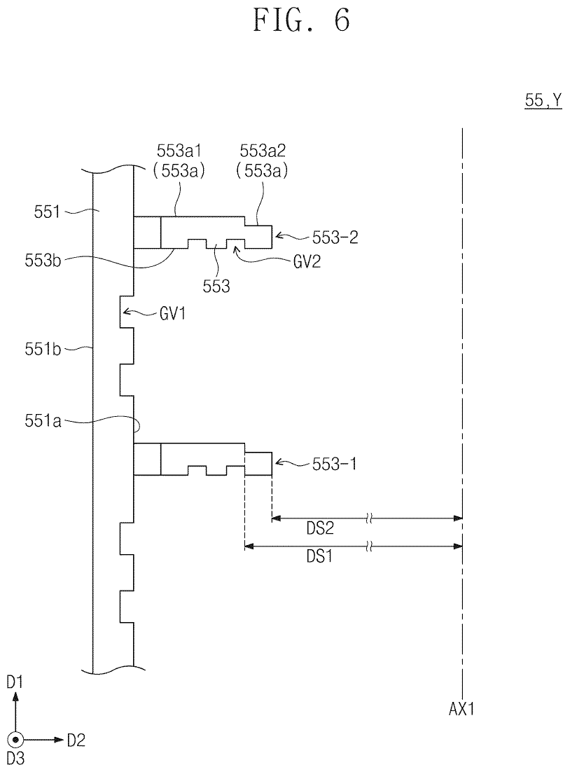

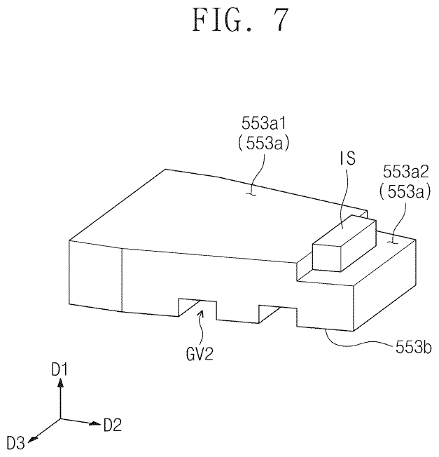

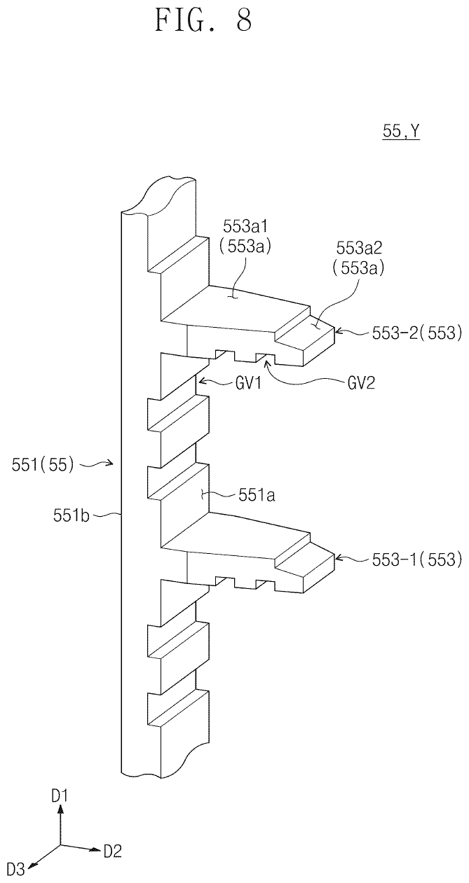

FIG. 4 is a perspective view showing a substrate support device 5 according to embodiments of the inventive concept, FIG. 5 is an enlarged perspective view of a portion of a substrate support device 5 according to embodiments of the inventive concept, FIG. 6 is a front view showing a portion of a substrate support device 5 according to embodiments of the inventive concept, FIG. 7 is an enlarged perspective view of a portion of a substrate support device 5 according to embodiments of the inventive concept, and FIG. 8 is a perspective view showing a substrate support device 5 according to embodiments of the inventive concept.

Referring to FIG. 4, a substrate support device 5 may include a lower support member 51 (e.g., a lower support), an upper support member 53 (e.g., an upper support), and a connector 55.

The lower support member 51 may have a plate shape which may generally extend in a horizontal plane. In detail, the lower support member 51 may have a disc plate shape. However, the shape of the lower support member 51 is not limited thereto. The lower support member 51 may include a through hole 51h in a center thereof. The lower support member 51 may have a ring shape. The lower support member 51 may have the first axis AX1 as a central axis thereof. The first axis AX1 may extend in a first direction (e.g., a vertical direction perpendicular to the horizontal plane of the lower support member 51).

The upper support member 53 may be located on the lower support member 51. The upper support member 53 may have the same shape as the lower support member 51. The lower support member 51 and the upper support member 53 may include silicon (Si), carbon (C), and oxygen (O). However, the materials included in the lower support member 51 and the upper support member 53 are not limited thereto. The lower support member 51 and the upper support member 53 may further include other materials so that durability does not deteriorate even in a high temperature and high pressure environment.

The connector 55 may connect the lower support member 51 to the upper support member 53. The connector 55 may include the same material as the lower support member 51 and the upper support member 53. However, the material of the connector 55 is not limited thereto. The connector 55 will be described later.

Referring to FIGS. 5 and 6, the connector 55 may include a connection pillar 551 and a substrate support 553. The connection pillar 551 may extend parallel to the first axis AX1. The connection pillar 551 may extend in the first direction D1. The connection pillar 551 may have one of a cylinder shape or a square pillar shape, but is not limited thereto. Referring to FIG. 4, a plurality of connection pillars 551 may be provided. In detail, two or more connection pillars 551 may be provided. For convenience of description below, the plurality of connection pillars 551 may be described as singular. The connection pillar 551 may include a first groove GV1 recessed from an inner surface 551a of the connection pillar 551 toward an outer surface 551b of the connection pillar 551. The first groove GV1 will be described later.

The substrate support 553 may support the substrate WF. The substrate support 553 may be connected to the connection pillar 551. The substrate support 553 may extend from the connection pillar 551 toward the first axis AX1. A width of the substrate support 553 may become smaller toward the first axis AX1. However, the inventive concept is not limited thereto. For example, the substrate support 553 may maintain a width thereof as it extends toward the first axis AX1. A roughness of a surface layer (e.g., an upper surface layer) of the substrate support 553 may be improved (e.g., increased) through a surface process. The surface process may include an embossing process. The substrate support 553 may have a first level deviation, which is the difference between the highest level of the upper surface layer and the lowest level of the upper surface layer. The first level deviation may be about 11 μm to 15 μm. However, a range of the first level deviation is not limited thereto. A plurality of substrate supports 553 may be provided. The plurality of substrate supports 553 may include a first substrate support 553-1 and a second substrate support 553-2. The second substrate support 553-2 may be located on the first substrate support 553-1. A shape of the second substrate support 553-2 and a shape of the first substrate support 553-1 may be substantially the same. Hereinafter, when describing content that may be commonly applied to the plurality of substrate supports 553, the plurality of substrate supports 553 may be described as singular.

The substrate support 553 may include an upper surface. The upper surface 553a of the substrate support 553 may include a first upper surface 553al and a second upper surface 553a2. The first upper surface 553al may be connected to the connection pillar 551. The first upper surface 553al and the first axis AX1 may be spaced apart by a first distance DS1 (see, e.g., FIG. 6). The second upper surface 553a2 may be located at a vertical level lower than a vertical level of the first upper surface 553a1. In detail, the vertical level of the second upper surface 553a2 may be lower than the vertical level of the first upper surface 553al by about 0.1 mm to about 0.7 mm. The second upper surface 553a2 and the first axis AX1 may be spaced apart by a second distance DS2. The second distance DS2 may be smaller than the first distance DS1. That is, the second upper surface 553a2 may be located closer to the first axis AX1 than the first upper surface 553al is.

Referring to FIG. 7, the substrate support 553 may include an island IS (e.g., a protrusion). The island IS may extend from the second upper surface 553a2 in the first direction D1. The island IS may extend from a partial region of the second upper surface 553a2. For example, a surface area of an upper surface of the island IS may be smaller than a surface area of the second upper surface 553a2. The second upper surface 553a2 may surround a portion of the island IS when viewed in plan view. For example, a side surface of the island IS may contact a side surface of the substrate support 553 that extends vertically between the first upper surface 553al and the second upper surface 553a2. A vertical level of the upper surface of the island IS may be higher than a vertical level of the second upper surface 553a2 and a vertical level of the first upper surface 553al. However, a shape of the island IS is not limited thereto. The island IS may have other shapes that may increase the surface area of the substrate support device 5. The island IS may have different shapes capable of supporting the substrate WF.

Referring to FIGS. 5, 6, and 7, the first upper surface 553al and the second upper surface 553a2 may be perpendicular to the first direction D1. However, an inclination of the first upper surface 553al and the second upper surface 553a2 is not limited thereto. Referring to FIG. 8, the second upper surface 553a2 may be tilted downward as it extends toward the central axis AX1. The second upper surface 553a2 may be inclined toward the lower support member 51 as it extends toward the central axis AX1.

The substrate support 553 may include at least one second groove GV2 recessed from the lower surface 553b of the substrate support 553 toward the upper surface 553a of the substrate support 553. A width of the second groove GV2 in a radial direction (e.g., in a direction from the central axis AX1 to the connector 55) may be about 0.5 mm to about 2 mm. A depth of the second groove GV2 may be about 0.1 mm to 0.5 mm. However, the width and depth of the second groove GV2 are not limited thereto. The at least one second groove GV2 may include a plurality of second grooves GV2 arranged, for example, in the radial direction. As the number of second grooves GV2 increases, the width and depth of the second groove GV2 may be variously changed. The shape of the second groove GV2 will be described later.

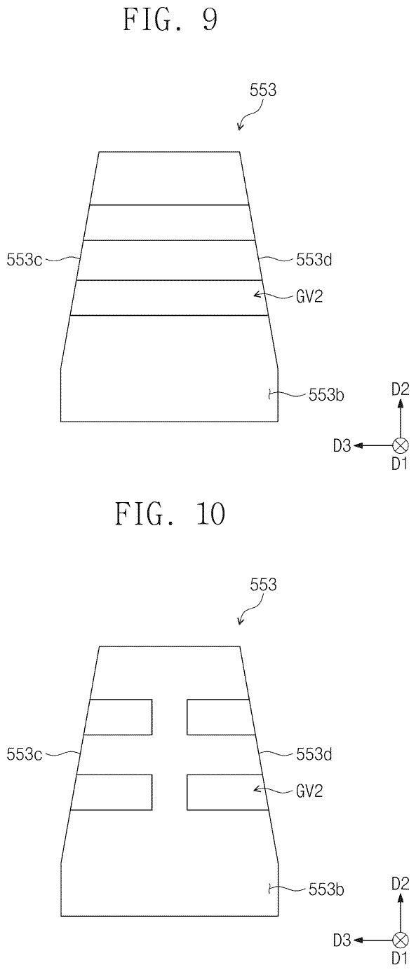

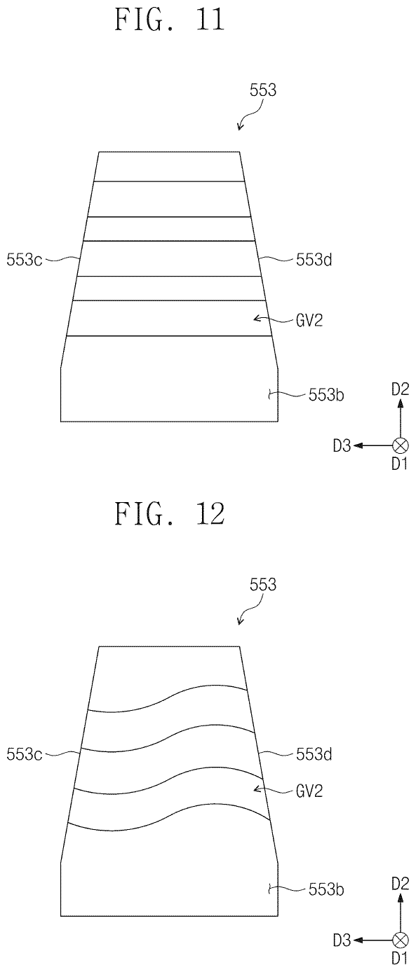

FIG. 9 is a bottom view showing a substrate support 553 according to embodiments of the inventive concept, FIG. 10 is a bottom view showing a substrate support 553 according to embodiments of the inventive concept, FIG. 11 is a bottom view showing a substrate support 553 according to embodiments of the inventive concept, and FIG. 12 is a bottom view showing a substrate support 553 according to embodiments of the inventive concept.

Referring to FIGS. 9, 10, 11, and 12, the second groove GV2 may have various shapes. Referring to FIG. 9, the second groove GV2 may have a straight shape. The second groove GV2 may penetrate the substrate support 553 horizontally. In other words, the second groove GV2 may extend from a left side 553c of the substrate support 553 to a right side 553d of the substrate support 553. However, the shape of the second groove GV2 is not limited thereto. Referring to FIG. 10, the second groove GV2 may not extend from the left side 553c of the substrate support 553 to the right side 553d of the substrate support 553. A length of the second groove GV2 may be smaller than a horizontal width of the substrate support 553. For example, each second groove GV2 may include a first portion extending from the left side 553c of the substrate support 553 toward the center of the substrate support 553 and a second portion, separate from the first portion, extending from the right side 553d of the substrate support 553 toward the center of the substrate support 553. Referring to FIGS. 9, 10, 11, and 12, a plurality of second grooves GV2 may be provided. Referring to FIG. 11, the number of second grooves GV2 may be three or more. As the number of second grooves GV2 increases, the width and depth of the second groove GV2 may be variously changed. Referring to FIG. 12, the second groove GV2 may have a wave shape. However, the shape of the second groove GV2 is not limited thereto. The second groove GV2 may have one of a straight line, a wavy shape, and an arc shape. The second groove GV2 may have a different shape that may increase the surface area of the substrate support 553.

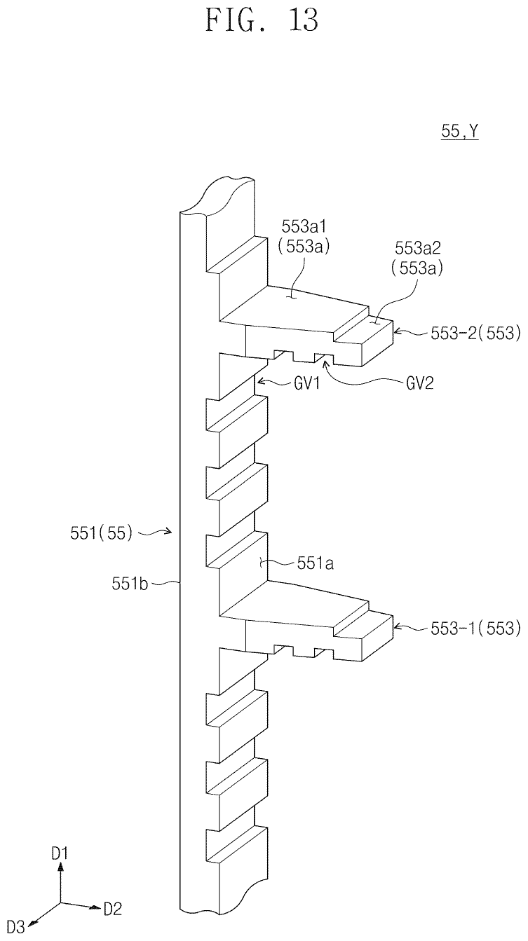

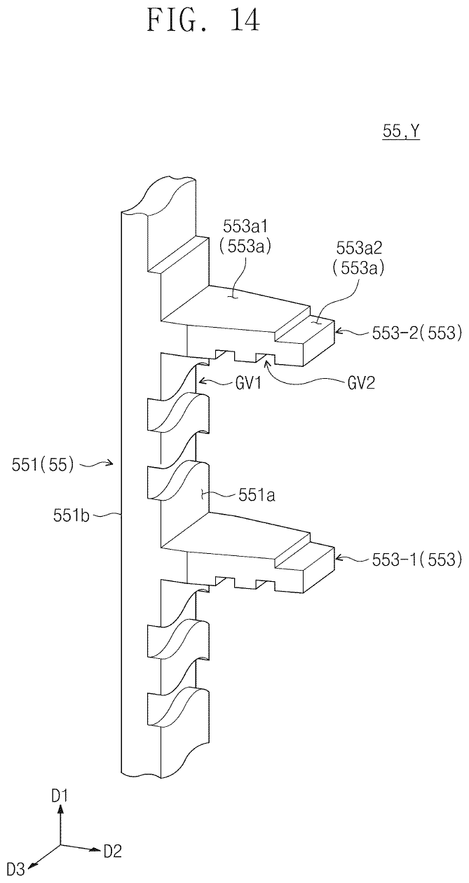

FIG. 13 is an enlarged perspective view of a portion of a substrate support device 5 according to embodiments of the inventive concept and FIG. 14 is an enlarged perspective view of a portion of a substrate support device 5 according to embodiments of the inventive concept.

Referring to FIGS. 5 and 13, a plurality of first grooves GV1 may be provided. Two or more first grooves GV1 may be provided. Hereinafter, for convenience of explanation, the plurality of first grooves GV1 may be described as singular. A depth of the first groove GV1 may be about 0.1 mm to about 0.5 mm. However, the depth of the first groove GV1 is not limited thereto. The first groove GV1 may have a straight shape extending from one side of the connector 55 to the other side of the connector 55. However, the shape of the first groove GV1 is not limited thereto. Referring to FIG. 14, the first groove GV1 may have a wave shape. In addition, the first groove GV1 may have a shape such as a curve or an arc shape. The first groove GV1 may have a different shape that is capable of expanding the surface area of the connection pillar 551.

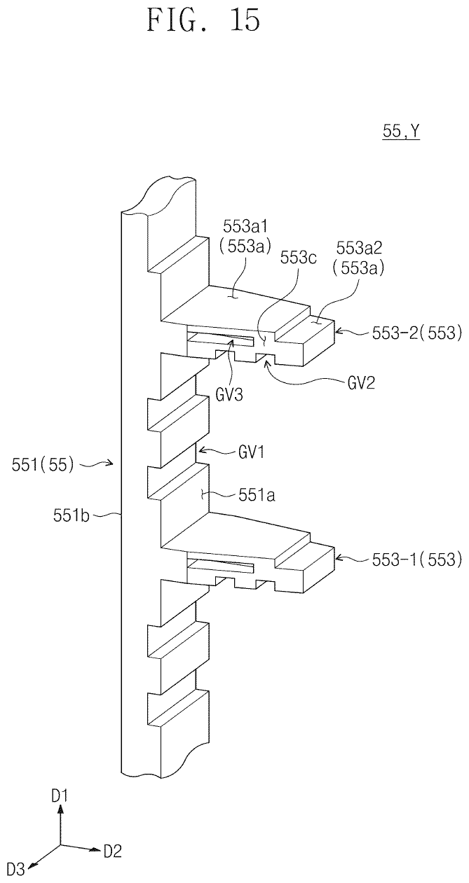

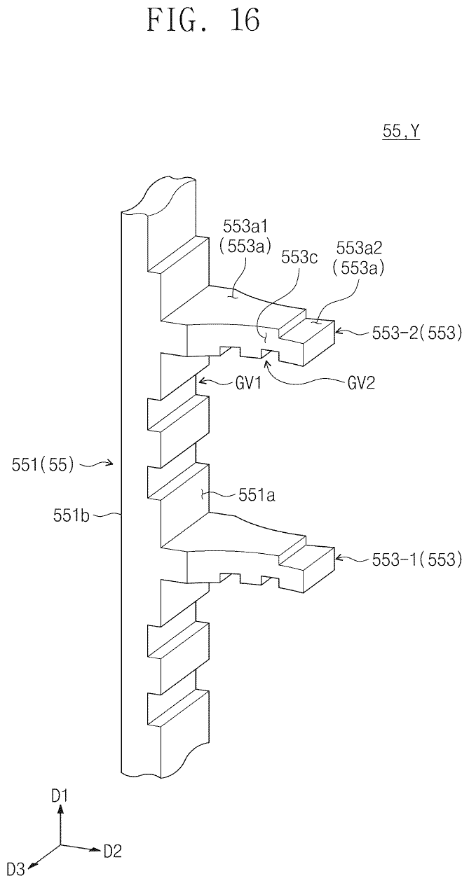

FIG. 15 is an enlarged perspective view of a portion of a substrate support device 5 according to embodiments of the inventive concept and FIG. 16 is an enlarged perspective view of a portion of a substrate support device 5 according to embodiments of the inventive concept.

Referring to FIGS. 15 and 16, other shapes that the substrate support device 5 may have may be provided. The substrate support device 5 may be provided with different grooves GV that are capable of increasing the surface area. Referring to FIG. 15, the substrate support 553 may include a third groove GV3 that is recessed from the left side 553c toward the inside of the substrate support 553. Alternatively, the substrate support 553 may include other grooves GV that are capable of increasing the surface area. The groove GV may be formed at a position other than the location where the first groove GV1, the second groove GV2, and/or the third groove GV3 are formed. Referring to FIG. 16, the left side 553c and right side 553d of the substrate support 553 may be curved. The upper surface 553a of the substrate support 553 may be bent in a downward direction as it extends toward the central axis AX1. The upper surface 553a of the substrate support 553 may be bent toward the lower support member 51 as it extends toward the central axis AX1.

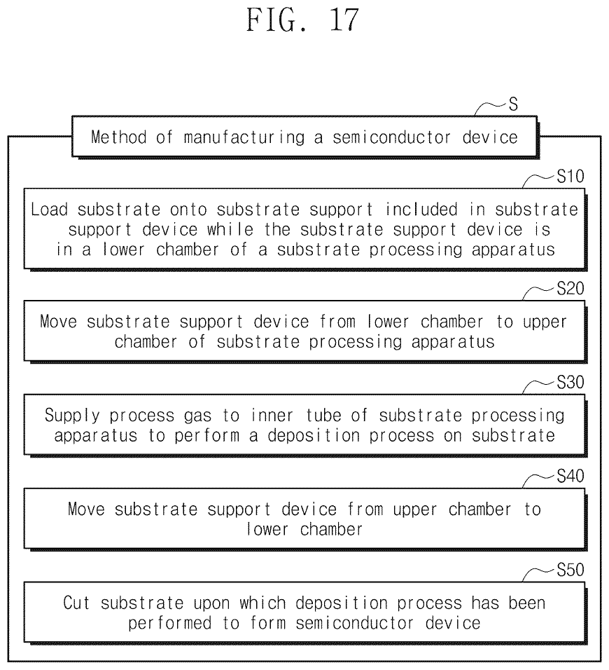

FIG. 17 shows a method of manufacturing a semiconductor device according to embodiments of the inventive concept.

Referring to FIG. 17, at step S10, at least one substrate (e.g., a wafer) WF may be loaded onto a substrate support device 5 while the substrate support device 5 is in a lower chamber CH2 of a substrate processing apparatus A. According to an embodiment, a plurality of substrates WF may be stacked in the substrate processing apparatus A.

At step S20, the support device driver BD may move the substrate support device 5 that has been loaded with the substrate WF from the lower chamber CH2 to the upper chamber CH1 of the substrate processing apparatus A.

At step S30, a process gas may be supplied to an inner tube 3 of the substrate processing apparatus A to be applied to the substrate WF. For example, a deposition process may be performed on the substrate WF using the supplied process gas.

At step S40, the support device driver BD may move the substrate support device 5 from the upper chamber CH1 back to the lower chamber CH2 so that the substrate WF may be unloaded from the substrate support device 5.

At step S50, the substrate WF may then be cut to form one or more semiconductor devices.

According to the substrate support apparatus according to embodiments of the inventive concept, the substrate support device may reduce foreign substances on the substrate by increasing the surface area of the substrate support device. As the surface area of the substrate support apparatus is increased, stress applied to the substrate support apparatus may be reduced. When the stress of the substrate support apparatus is reduced, peeling of one or more layers of the substrate support apparatus may be reduced, thereby reducing contamination of the substrate. The surface area of the substrate support apparatus may be expanded through processing the upper surface of the substrate support. A stepped upper surface of the substrate support may be provided, thereby expanding the surface area of the substrate support. Additionally, the island may be formed on the substrate support, thereby increasing the surface area of the substrate support. The surface area of the substrate support apparatus may be expanded through the grooves. The connection pillar may include the first groove. The substrate support may include the second groove and the third groove. However, as mentioned above, the groove is not limited to the positions mentioned in this specification. The surface area of the substrate support apparatus may also be increased by improving (e.g., increasing) the surface roughness. As the surface roughness improves, the surface area of the substrate support apparatus may be expanded.

According to the substrate support apparatus of an aspect of the inventive concept, the surface area of the connector may be increased.

According to the substrate support apparatus of an aspect of the inventive concept, the contact area between the substrate support and the substrate may be expanded by processing the upper surface of the substrate support.

According to the substrate support apparatus of an aspect of the inventive concept, the surface area of the substrate support may be expanded by processing the lower surface of the substrate support to provide the groove.

According to the substrate support apparatus of an aspect of the inventive concept, the surface area of the connection pillar may be expanded by processing the connection pillar and providing the groove.

The effects of the inventive concept are not limited to the effects mentioned above, and other effects not mentioned will be clearly understood by those skilled in the art from the description above.

While embodiments are described above, a person skilled in the art may understand that many modifications and variations are made without departing from the spirit and scope of the inventive concept. Accordingly, the example embodiments of the inventive concept should be considered in all respects as illustrative and not restrictive.

What is claimed is:

1. A substrate support apparatus comprising:
a lower support having a plate shape and having a first axis as a central axis extending in a vertical direction perpendicular to a horizontal plane of the lower support;
an upper support on the lower support; and
a connector connecting the lower support to the upper support,
wherein the connector includes:
a connection pillar extending parallel to the first axis; and
at least one substrate support connected to the connection pillar and extending from the connection pillar toward the first axis,
wherein an upper surface of the at least one substrate support includes:
a first upper surface connected to the connection pillar; and
a second upper surface positioned at a vertical level lower than a vertical level of the first upper surface, and
wherein a first distance between the first upper surface and the first axis is larger than a second distance between the second upper surface and the first axis.

2. The substrate support apparatus of claim 1, wherein the vertical level of the second upper surface is about 0.1 mm to 0.7 mm lower than the vertical level of the first upper surface.

3. The substrate support apparatus of claim 1, wherein each of the at least one substrate support includes at least one first groove recessed from a lower surface of the at least one substrate support toward the upper surface of the at least one substrate support.

4. The substrate support apparatus of claim 3, wherein the at least one first groove includes two or more first grooves.

5. The substrate support apparatus of claim 3, wherein the at least one first groove has a width of about 0.5 mm to 2 mm, and
wherein the at least one first groove has a depth of about 0.1 mm to 0.5 mm.

6. The substrate support apparatus of claim 3, wherein the at least one first groove has one of a straight shape, a wavy shape, and an arc shape when viewed from a bottom view.

7. The substrate support apparatus of claim 1, wherein the at least one substrate support includes a protrusion extending from the second upper surface in the vertical direction,
wherein the second upper surface surrounds a portion of the protrusion when viewed in plan view, and
wherein a vertical level of an upper surface of the protrusion is higher than the vertical level of the first upper surface.

8. The substrate support apparatus of claim 1, wherein the connection pillar includes a second groove recessed from an inner surface of the connection pillar toward an outer surface of the connection pillar.

9. The substrate support apparatus of claim 8, wherein the second groove has a depth of about 0.1 mm to 0.5 mm.

10. The substrate support apparatus of claim 8, wherein the at least one substrate support includes a plurality of substrate supports,
wherein the plurality of substrate supports includes:
a first substrate support; and
a second substrate support on the first substrate support, and
wherein the second groove is at a vertical level between the first substrate support and the second substrate support.

11. The substrate support apparatus of claim 1, wherein the substrate support includes one of silicon (Si), silicon nitride (SiN), and silicon phosphide (SiP).

12. A substrate support apparatus comprising:
a lower support having a plate shape and having a first axis as a central axis extending in a vertical direction perpendicular to a horizontal plane of the lower support;
an upper support on the lower support; and
a connector connecting the lower support to the upper support,
wherein the connector includes:
a connection pillar extending parallel to the first axis; and
at least one substrate support extending from the connection pillar toward the first axis, and
wherein each of the at least one substrate support includes at least one first groove recessed from a lower surface of the at least one substrate support toward an upper surface of the at least one substrate support.

13. The substrate support apparatus of claim 12, wherein the at least one first groove has one of a straight line shape, an arc shape, and a wave shape when viewed from a bottom view.

14. The substrate support apparatus of claim 12, wherein the at least one first groove includes a plurality of first grooves.

15. The substrate support apparatus of claim 12, wherein the upper surface of the at least one substrate support includes:
a first upper surface connected to the connection pillar; and
a second upper surface farther from the connection pillar than the first upper surface, and
wherein a vertical level of the second upper surface is lower than a vertical level of the first upper surface.

16. The substrate support apparatus of claim 15, wherein the second upper surface is inclined toward the lower support.

17. The substrate support apparatus of claim 12, wherein the connection pillar includes a second groove recessed from an inner surface of the connection pillar toward an outer surface of the connection pillar.

18. The substrate support apparatus of claim 17, wherein the at least one substrate support includes a plurality of substrate supports,
wherein the plurality of substrate supports includes:
a first substrate support; and
a second substrate support on the first substrate support, and
wherein a vertical level of the second groove is higher than a vertical level of the upper surface of the first substrate support and lower than a vertical level of a lower surface of the second substrate support.

19. A substrate support apparatus comprising:
a lower support having a plate shape and having a first axis as a central axis extending in a vertical direction perpendicular to a horizontal plane of the lower support;
an upper support on the lower support; and
a connector connecting the lower support to the upper support,
wherein the connector includes:
a connection pillar extending parallel to the first axis; and
at least one substrate support extending from the connection pillar toward the first axis, and
wherein the connection pillar includes a groove recessed from an inner surface of the connection pillar toward an outer surface of the connection pillar.

20. The substrate support apparatus of claim 19, wherein the at least one substrate support includes a plurality of substrate supports,
wherein the plurality of substrate supports includes a first substrate support and a second substrate support on the first substrate support, and
wherein the groove is at a vertical level between the first substrate support and the second substrate support.
